(19) United States
(12) Patent Application Publication
(10) Pub. No.: US 2011/0143553 A1
(43) Pub. Date: Jun. 16, 2011

(54) INTEGRATED TOOL SETS AND PROCESS TO KEEP SUBSTRATE SURFACE WET DURING PLATING AND CLEAN IN FABRICATION OF ADVANCED NANO-ELECTRONIC DEVICES

(75) Inventors: Yaxin Wang, Fremont, CA (US); Shijian Li, San Jose, CA (US); Fritz Redeker, Fremont, CA (US); John Parks, Fremont, CA (US); Artur Kolics, Dublin, CA (US); Hyungsuk Alexander Yoon, San Jose, CA (US); Tarek Suwwan de Felipe, Fremont, CA (US); Mikhail Korolik, San Jose, CA (US)

(73) Assignee: Lam Research Corporation, Fremont, CA (US)

(21) Appl. No.: 12/965,765

(22) Filed: Dec. 10, 2010

Related U.S. Application Data
(60) Provisional application No. 61/285,950, filed on Dec. 11, 2009.

(51) Int. Cl. H01L 21/469; B05C 3/02; B05C 11/00; B05C 11/02

(52) U.S. Cl. 438/782; 118/423; 118/73; 118/100

(57) ABSTRACT

Methods and systems for handling a substrate through processes including an integrated electroless deposition process includes processing a surface of the substrate in an electroless deposition module to deposit a layer over conductive features of the substrate using a deposition fluid. The surface of the substrate is then rinsed in the electroless deposition module with a rinsing fluid. The rinsing is controlled to prevent de-wetting of the surface so that a transfer film defined from the rinsing fluid remains coated over the surface of the substrate. The substrate is removed from the electroless deposition module while maintaining the transfer film over the surface of the substrate. The transfer film over the surface of the substrate prevents drying of the surface of the substrate so that the removing is wet. The substrate, once removed from the electroless deposition module, is moved into a post-deposition module while maintaining the transfer film over the surface of the substrate.

### CLAIM OF PRIORITY

This application claims the priority of U.S. Provisional Application No. 61/285,950, filed on Dec. 11, 2009, and titled “Integrated Tool Sets and Process to Keep Substrate Surface Wet During Plating and Clean in Fabrication of Advanced Nano-Electronic Devices.” This application is incorporated herein by reference in its entirety for all purposes.

### CROSS REFERENCE TO RELATED APPLICATIONS

This application is related to U.S. patent application Ser. No. 11/760,722, filed on Jun. 8, 2007, and entitled “Semiconductor System with Surface Modification,” and to PCT Application No. PCT/US09/55943, filed on Sep. 3, 2009, and entitled “Cleaning Solution Formulations for Substrates.” The disclosure of these applications are incorporated herein by reference.

### FIELD OF THE INVENTION

The present invention relates generally to semiconductor substrate processing, and more particularly, to the handling of a substrate through an integrated electroless deposition process during fabrication.

### DESCRIPTION OF THE RELATED ART

In the fabrication of semiconductor devices such as integrated circuits, memory cells, and the like, a series of fabrication operations are performed to define multilevel features on semiconductor substrates (“substrates”). Features having multiple levels are becoming more prevalent as device dimensions fall to the sub-micron levels and there is constant demand to increase the density of devices in order to provide greater computational capacity.

The series of fabrication operations involve selectively removing (etching) or depositing different materials on the surface of the substrate. The fabrication operations start at a substrate level where transistor or capacitor devices with diffusion regions are formed. A first layer of dielectric (insulating) material is deposited on top of the formed transistors. In subsequent levels, interconnect metallization lines are patterned on top of the base layer as multiple thin-film layers through a series of manufacturing process steps. The interconnect metallization lines electrically connect to the underlying transistor or capacitor devices by way of contacts to thereby define a desired circuit. The patterned conductive layers are insulated from each other by layers of dielectric materials.

Copper is becoming a conductor of choice for most device interconnects due to its lower resistivity and lower susceptibility to electro-migration as compared to aluminum. Electro-migration is the transportation of material caused by the gradual movement of ions in a conductor due to momentum transfer between conducting electrons and diffusing metal atoms. Electro-migration decreases the reliability of integrated circuits (ICs). In the worst case, electro-migration leads to eventual loss of one or more connections resulting in intermittent failure of the entire circuit.

One commonly used method of patterning copper is called Copper Damascene Process, in which a substrate with patterned trenches undergoes an interconnect deposition (plating) process of copper after a barrier layer. During the deposition process, a copper seed layer is deposited on the top, along bottom and on the side walls of the patterned trenches. The top surface of copper will be polished with a subsequent chemical-mechanical polishing (CMP). Such steps leave copper lines or pads well defined with copper metal exposed on the top surface, but well isolated between dielectrics across the surface of the substrate.

A great effort has been made to alter or to modify copper surface property so as to drastically improve electro-migration properties of interconnect copper lines and to improve the interface property of copper with subsequent material deposited over the copper. Among them, capping of the top copper surface with cobalt alloys through electroless deposition (ELD) is proved the most effective technology to deliver required integrated performance of advanced nano-devices. ELD allows a selective and self-catalytic deposition of another metal over Cu lines, with essential absence of deposition over the dielectric layer. This selective process permits to preserve the electrical insulation between the interconnect lines, whilst providing the necessary capping to copper interconnect so as to enhance interface adhesion strength, and minimize the rate of electro-migration.

In the copper damascene process, the copper line is encapsulated on the sides and bottom by barrier metal, and on top by barrier/etch stop dielectric. The copper/dielectric interface has weaker adhesion than the copper/barrier metal interface, so copper precipitation occurs predominantly at the top surface. Under high current densities, copper electro-migration (EM) would cause atoms to move in the direction of the electron flow ultimately causing the device to fail. Attempts to improve copper/dielectric adhesion by inserting a barrier layer on top would not only require additional expensive patterning and etching procedures but also greatly increase the line resistivity. A better alternative to inserting a barrier layer is to add a cobalt tungsten phosphide (CoWP) cap to the copper using a selective ELD process after CMP. It has been demonstrated, in some cases, that using a CoWP cap has resulted in EM lifetime improvements of one to two orders of magnitude, compared with structures using the conventional dielectric layer alone. However, adding CoWP cap to the copper has its own problems. For instance, the un-capped copper and by-products of previous process steps can diffuse into the surrounding dielectric layer. The diffusion may cause migration of electrically conducting metal species into the porous dielectric layer potentially leading to high electric leakage.

After the capping operation, the substrate is then dried before moving the substrate out of the plating module to a subsequent processing module, such as a brush scrub module, a chemical module and/or a combined brush-rinse-and-dry module, for further processing. The substrate, of course, must be dried up in the rinse-and-dry module before the next manufacturing procedure of dielectric deposition. However, premature drying of the substrate between the ELD module and the final rinse-and-dry module would cause a serious issue. No matter how extensive the post-deposition rinse is in the ELD module, a low level of the metal ions exist in the liquid on top of the substrate. The metal ions could be cobalt ions resulting from constant dissolution of the metal in the aqueous solution on the substrate surface. The subsequent substrate drying in the ELD module could be a spin-dry process. The spin-dry process always leaves a very thin layer of liquid on some area of the substrate surface, that, of course, contains a higher concentration of the metal ions since it is the closest to the metal surface. The metal ions, once dissolved, are not localized only above the metal lines or pads, but will diffuse horizontally within the liquid layer.

Upon the final evaporation of the last bit of liquid solvent, the concentration of the metal ions can easily exceed the critical concentration and will thus be forced to precipitate out as conductive residues or contaminants covering metal lines, pads and the dielectric surface alike.

Worse, since the ELD module is not designed (optimized) for spin-dry, numerous liquid drops originally released from the substrate surface may unavoidably splash back onto the almost-dried substrate surface. Such small and fine drops would not be spun off. Instead, these fine drops would dry up to leave additional thicker residues or contaminants on the substrate surface, metal top and the dielectric top alike. These residues or contaminants, if not cleaned up, would seriously affect the time dependent dielectric breakdown (TDDB). If these residues/contaminants are to be cleaned up by the way of wet-etching, however, the integrity of the CoWP capping on top of the copper would be destroyed exposing copper at the copper-barrier interface, since there is no CoWP deposition on the barrier material.

Although problems with the conventional process have been explained in great detail with reference to copper (due to preferred conductive metal of choice), it should be noted such problems are prevalent with other conductive metals that are used for defining device interconnects.

It is in this context embodiments of the invention arise.

### SUMMARY

Broadly speaking, the embodiments fill the need by providing improved apparatus, systems and methods to keep substrate surface wet while handling the substrate through an integrated electroless deposition process before a final dry operation. Accordingly, the surface of the substrate is processed in an electroless deposition (ELD) module to deposit a layer over conductive features of the substrate using a deposition fluid. After successfully depositing the layer, the surface of the substrate can be rinsed with a post-deposition rinsing fluid such as DIW in the ELD module to largely rinse off the deposition solution from the surface of the substrate. In one embodiment, with or without the DIW rinse, the substrate is rinsed with a rinsing fluid in the electroless deposition module. The rinsing is controlled to prevent de-wetting of the surface of the substrate. The rinsing enables, the rinsing fluid to be coated over the surface of the substrate. The rinsing fluid acts as a transfer film that prevents the surface of the substrate from drying and from being exposed to ambient air while ensuring that the surface of the substrate is kept wet during removal from the electroless deposition module. The substrate is removed out of the electroless deposition module with the transfer film over the surface of the substrate. The substrate is moved into a subsequent post-deposition module while maintaining the transfer film over the surface of the substrate till the start of the next process step.

The current embodiments address the drawbacks faced by conventional deposition process which involve pre-mature drying of the substrate between the ELD process and the final rinse-and-dry process. Specifically, the current embodiments address the issue of premature drying by ensuring that a post-deposition fluid film (which can be a chemical used for treating the surface of the substrate) uniformly covers the substrate surface keeping the substrate wet upon conclusion of the deposition process before subsequent cleaning process. In one embodiment, the substrate is kept wet while the substrate is transported out of the electroless deposition module into a subsequent processing module prior to rinse-and-dry module. The presence of the transfer film on the surface of the substrate defined by the post-deposition rinsing fluid ensures that damage due to precipitation and diffusion of processing chemistry or damage due to precipitation of contaminants and other impurities from the ambient environment are avoided.

With respect to issues associated with precipitation and diffusion, the conventional deposition process allows the substrate to be spin-dried to remove the deposition fluid from the surface of the substrate before moving the substrate out of the deposition module. However, because of the high moisture content within the deposition module, one or more droplets of the deposition fluid may precipitate on the surface of the substrate while the substrate is being moved out of the deposition module, resulting in damage to the active features formed on the substrate. Such damage is clearly avoided in the embodiments of the present invention by maintaining a layer of post-deposition fluid film on the surface of the substrate. As a layer of the post-deposition fluid film is already present on the surface of the substrate, an additional drop or two of the rinsing fluid settling on the surface of the substrate in the highly moist electroless deposition module will not adversely affect the active features formed on the surface of the substrate. In one embodiment, the post-deposition fluid film is a treating chemical film that acts as a barrier preventing the metal formed on the surface of the substrate and the interlayer dielectric (ILD) from getting exposed to the ambient air thereby reducing metal oxidation, chemical reaction and transformation of the materials on the surface of the substrate. In one embodiment, it is important to insulate the ILD from the ambient air as exposure to ambient air may result in metallic or ionic precipitations on the porous ILD surface resulting in increased “talk” between interconnection lines. The increased talk would result in increased leakage current thereby worsening electro-migration.

Further, the wet-dry cycles of the conventional deposition process enhance the level of contaminants on the ILD, which directly result in increased leakage current. The increased leakage current would cause increased total current density, and thus worsen electro-migration and eventually worsen time dependent dielectric breakdown (TDDB). By removing existing contaminants and preventing other contaminants to agglomerate on the surface of and inside the treated surface, the insulating properties of the ILD between metal lines and layers are maintained thereby ensuring that the TDDB is not affected. Further, in the convention process, the diffusion of electrically active species, such as copper, derivatives of copper and other metal derivatives, result in electric leakage or shorts between copper metal lines leading to the malfunction of the device formed therein. The current embodiments avoid the wet-dry cycles reducing the diffusion of metals' derivatives into the porous dielectric surface thereby avoiding the ensuing current leakage in the devices formed therein significantly increasing the electrical yield of the devices.

It should be appreciated that the present invention can be implemented in numerous ways, including methods, an apparatus, and a system. Several inventive embodiments of the present invention are described below.

In one embodiment a method for handling a substrate through processes including an integrated electroless deposition process is disclosed. The method includes processing a surface of the substrate in an electroless deposition module to deposit a layer over conductive features of the substrate using a deposition fluid. The surface of the substrate is then rinsed in the electroless deposition module with a rinsing fluid. The rinsing is controlled to prevent de-wetting of the surface so that a transfer film defined from the rinsing fluid remains coated over the surface of the substrate. The substrate is removed from the electroless deposition module while maintaining the transfer film over the surface of the substrate. The transfer film over the surface of the substrate prevents drying of the surface of the substrate so that the removing is wet. The substrate, once removed from the electroless deposition module, is moved into a post-deposition module while maintaining the transfer film over the surface of the substrate.

In another embodiment, a method for handling a substrate through processes including an integrated electroless deposition process is disclosed. The method includes processing a surface of the substrate in an electroless deposition module to deposit a layer over conductive features of the substrate using a deposition fluid The surface of the substrate is then rinsed with a rinsing fluid in the electroless deposition module. A treating fluid is applied in the electroless deposition fluid. The treating fluid defines a transfer film. The application of the treating fluid is controlled to prevent de-wetting of the surface and to chemically treat the surface while the transfer film remains coated over the surface of the substrate. The substrate is removed out of the electroless deposition module while the transfer film is maintained over the surface of the substrate. The transfer film prevents drying of the surface of the substrate so that the substrate is removed wet. The substrate, once removed from the electroless deposition module, is moved into a post-deposition module while maintaining the transfer film over the surface of the substrate.

In yet another embodiment, a system for handling a substrate through processes including an integrated electroless deposition process is disclosed. The system includes an electroless deposition module that is configured to process a surface of a substrate by depositing a layer of deposition fluid on conductive features formed on the substrate and to control the application of a fluid that prevents de-wetting and applies a coating of the fluid over the surface of the substrate. The system also includes a wet robot that is configured to remove the substrate out of the electroless deposition module while maintaining the coating of the fluid over the surface of the substrate and to move the substrate into a post-deposition module while maintaining the coating of the fluid over the surface of the substrate.

In another embodiment, a system for handling a substrate through processes including an integrated electroless deposition process is disclosed. The system includes an electroless deposition module that is configured to supply a deposition fluid, wherein the deposition fluid is used to deposit a layer over conductive features formed on a surface of the substrate; apply a rinsing fluid to rinse the surface of the substrate, after depositing the layer; and to apply a treating fluid to the surface of the substrate, wherein the treating fluid defines a transfer film. The electroless deposition module includes control to control the application of the treating fluid to prevent de-wetting of the surface and to chemically treat the surface while the transfer film is maintained over the surface of the substrate. The system also includes a wet robot that is configured to remove the substrate out of the electroless deposition module while maintaining the transfer film over the substrate, wherein the transfer film prevents drying of the substrate so that the substrate is removed wet from the electroless deposition module; and to move the substrate into a post-deposition module while maintaining the transfer film over the substrate.

The integrated electroless deposition process provides selective deposition of deposition fluid to cap the conductive features on the surface of the substrate while preventing oxidation, other chemical reactions and transformations of materials formed on the surface of the substrate. The post-deposition fluid film prevents any contaminants, residues of chemistries from damaging the ILD and metal features on the surface of the substrate resulting in high electrical yield of devices defined on the surface of the substrate.

Other aspects and advantages of the invention will become apparent from the following detailed description, taken in conjunction with the accompanying drawings, illustrating by way of example the principles of the invention.

### BRIEF DESCRIPTION OF THE DRAWINGS

The invention will be readily understood by reference to the following description taken in conjunction with the accompanying drawings. These drawings should not be taken to limit the invention to the preferred embodiments, but are for explanation and understanding only. Like reference numerals designate like structural elements.

FIG. 1 illustrates a simplified diagram of an electroless deposition capping process, in one embodiment of the invention.

FIG. 2A illustrates a cross-sectional block representation of an ELD module used in the integrated electroless deposition process of a substrate, in one embodiment of the invention.

FIG. 2B illustrates a schematic top view of an ELD module, with a lid opened, used in the deposition process, in one embodiment of the invention.

FIG. 2C illustrates a schematic top view of the ELD module illustrated in FIG. 2B (lid removed for illustration purposes only), in one embodiment of the invention.

FIG. 3A illustrates a simplified block diagram of various modules and components within an electroless deposition system for handling the substrate during the integrated electroless deposition process, in one embodiment of the invention.

FIG. 3B illustrates a simplified block diagram of various modules and components within an electroless deposition system for handling the substrate during the integrated electroless deposition process, in an alternate embodiment of the invention.

FIG. 4A illustrates a simplified process sequence of various steps involved in the integrated electroless deposition process, in one embodiment of the invention.

FIG. 4B illustrates a simplified process sequence of steps involved in the integrated electroless deposition process, in an alternate embodiment of the invention.

FIG. 5A illustrates various operations carried out in the components of an electroless deposition system, in one embodiment of the invention.

FIG. 5B illustrates various operations carried out in the components of an electroless deposition system, in an alternate embodiment of the invention.

FIG. 6 illustrates a flowchart of operations used in the deposition process, in one embodiment of the invention.

FIG. 7 illustrates a flowchart of operations used in the deposition process, in an alternate embodiment of the invention.

### DETAILED DESCRIPTION

Several embodiments for handling a substrate efficiently through processes including an integrated electroless deposition (ELD) process will now be described. The various embodiments describe an ELD process wherein the substrate undergoes a deposition in an electroless deposition module to cap conductive features formed on the surface of the substrate and then a transfer film is applied to wet the surface of the substrate. A transfer film, as used in this application, is a chemical, such as de-ionized water (DIW), with or without a surfactant that acts to provide a barrier so as to protect the underlying features/components from getting exposed to the ambient air. The substrate with the transfer film wetting the surface is transferred from the ELD module or a post-deposition module to a subsequent post-deposition module within the system for further processing.

It should be noted, that exemplary embodiments have been described to provide an understanding of the invention. It will be obvious, however, to one skilled in the art, that the present invention may be practiced without some or all of these specific details. In other instances, well known process operations have not been described in detail in order not to unnecessarily obscure the present invention.

The transfer film on the surface of the substrate acts as a barrier to reduce oxidation, other chemical reactions and/or transformation of the materials on the surface of the substrate. Transformation, as used in this application, defines a change in chemical properties of a material due to chemical reaction such that the resulting material includes chemical properties that are substantially different from the material. The chemical transformation of the material may result in device malfunctions due to the difference in the properties of the transformed material. The transfer film also prevents contaminants and other residues from precipitating on the surface of the substrate and compromising the characteristics of the dielectric as well as the conducting material. Further, the transfer film on the substrate surface prevents defects from being formed due to premature drying of the surface of the substrate both during process and during transfer between modules.

Conventional ELD system enabled selective deposition to be performed on the surface of the substrate within an ELD module. Upon successful deposition, the surface of the substrate was rinsed to remove any chemicals and residues left behind on the surface of the substrate from the deposition process and dried before transporting the substrate out of the ELD module to a post-deposition module where additional processing was performed. The wet-dry cycle of the conventional ELD system caused pre-mature drying of the substrate surface and resulted in moisture breaks, oxide removal and re-oxidations. The re-oxidation causes undesirable metal line corrosion thereby weakening interconnection of metal lines of a device. The pre-mature drying leaves defects and contaminants on the substrate surface that results in device malfunctions leading to substantial yield loss. The frequent moisture breaks also enable contaminants released from the surface of the substrate into the ambient air to precipitate on the surface of the substrate causing further damage to the devices. Thus, using the conventional ELD deposition process, the desirable capping property on the copper surface cannot be delivered, significantly compromising the key electric properties of advanced nano-devices due to time dependent dielectric breakdown (TDDB) and electro-migration. This results in electrical yield loss and degradation in device reliability.

In order to best take advantage of ELD capping and to improve advanced nano-devices reliability with enhanced electrical yield and minimized device malfunctions, novel systems, apparatuses and methods are disclosed that use an integrated electroless deposition module to perform a deposition process to cap (e.g. with cobalt, CoWP) conductive features (e.g. copper) after a fabrication operation, such as chemical-mechanical polishing (CMP), and to apply a film of post-deposition fluid after the deposition process to coat the surface of the substrate so as to prevent de-wetting. The post-deposition fluid defines a transfer film on the surface of the substrate. The substrate is transported wet with the transfer film covering the surface of the substrate from the ELD module to a post-deposition module for further processing. A wet robot is used to assist in the transportation of the wet substrate from one module into another for further processing of the substrate. After substantial processing, the substrate is transported wet with such a transfer film covering the surface of the substrate to a clean module where the substrate is rinsed and dried. The rinsed and dried substrate is transported out of the ELD system using a dry robot. By removing contaminants and not allowing other contaminants to agglomerate on the treated surface of the substrate, the insulating properties of the ILD between metal layers is maintained and the electrical enhancements provided by the capping layer, such as CoWP capping layer, is realized, thereby resulting in optimization of the time dependent dielectric breakdown (TDDB). The resulting substrate is substantially clean, devoid of defects caused due to oxidation, other chemical reaction or transformation of the materials and has a substantial electrical yield due to minimal wet-dry cycles.

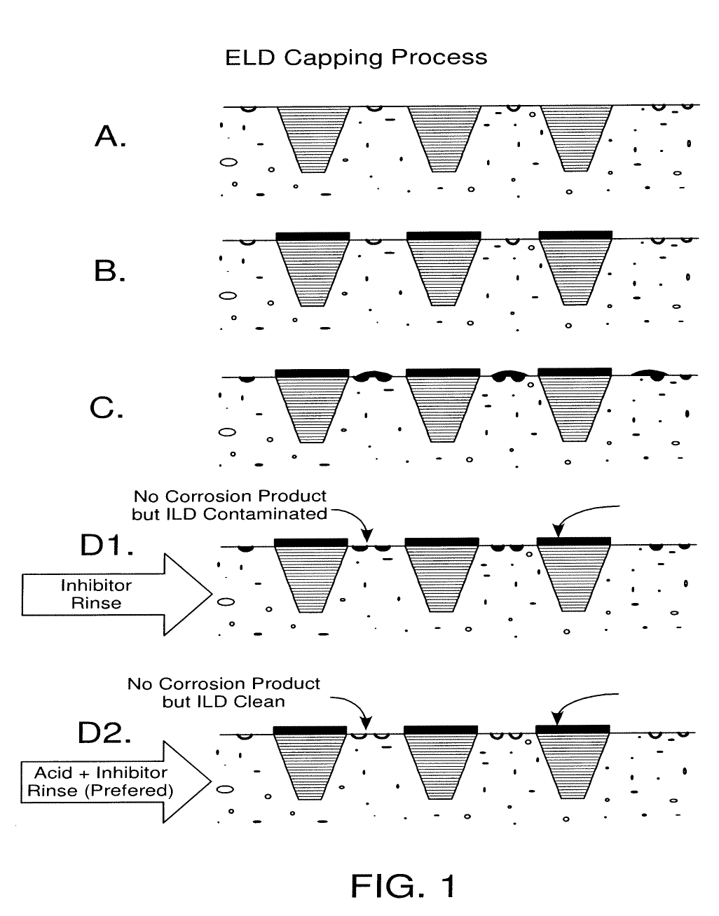

In order to better understand the various advantages of the ELD system, various embodiments will now be described with reference to the attached drawings. FIG. 1 illustrates a sample electroless deposition (ELD) capping process used in a conventional fabrication process in order to understand the problems associated with the conventional process. The ELD capping process is normally performed after the substrate undergoes copper deposition to form layers of interconnections on a surface of a substrate. Copper deposition is well known in the industry and is typically accomplished by means of an electroplating apparatus. It is therefore not discussed in depth in this application. After the deposition of copper, a fabrication operation, such as chemical mechanical polishing (CMP), is performed to planarize the deposited copper and to remove the excess copper and barrier material deposited on the surface of the substrate including on the dielectric surface. The planarization of the copper can be performed using any conventional CMP methods that are currently available in the industry and hence have not been discussed in depth here.

After successful planarization, the surface of the substrate is cleaned to remove residues and contaminants left behind by the planarization operation (e.g. cu-based particles on the dielectric) and subsequent oxidation. Following the planarization process, the substrate is treated to an Electroless Deposition (ELD) process wherein the exposed conductive features, such as copper interconnects, are capped. A typical capping process uses a chemical with cobalt based alloy. The cobalt capping reduces electro-migration of copper over the course of the lifetime of the device, which would otherwise concentrate in certain regions and create a void or open in other regions (resulting in device failure, aka EM). Further, cobalt capping may assist in preventing copper from diffusing into dielectric material surrounding the area where copper is deposited on the surface of the substrate. Due to the porosity of the dielectric material, the precipitation of the copper and cobalt derivatives left on the surface or in pores of the dielectric material can compromise the characteristics of the low-k dielectric material resulting in device malfunctions. The benefits of CoWP capping are realized so long as the electrical integrity of the existing ILD can be preserved.

Referring back to FIG. 1, the figure illustrates an exemplary ELD capping process following the CMP process. Copper deposited on the surface to form interconnects to the underlying devices, is planarized using a conventional chemical-mechanic polishing (CMP) method and the substrate surface is rinsed to remove any residues from the planarization operation, as shown in step A. Subsequent to the planarization and rinsing operations, a capping process using electroless deposition is performed using capping chemical to cap the conductive features on the surface of the substrate, as shown in step B. In one embodiment, the capping chemical is a cobalt-rich chemical alloy so that a cobalt alloy cap (CoWP) can be provided on the conductive features. The capping operation is followed by a post-deposition rinse to remove the residues from the substrate surface and includes the application of a layer of passivating (treating chemical or rinsing) fluid which does not allow for contaminants to attach to the ILD, as illustrated in step D1. The treating chemical fluid layer also prevents further deposition of cobalt on undesired areas of the substrate.

Typically with the device dimensions reaching the sub-micron levels, the width of the conductive features, such as copper metal lines, that provide interconnects to the underlying devices, are in the sub-100 nanometer range with some having a width below 50 nanometers. In such cases, the capping normally is less than about 10 nanometers. The typical capping process of applying a cobalt-rich chemical as shown in step B of FIG. 1, however, results in contaminating the interlayer dielectric material (ILD). Without an effective post-deposition rinse following the capping operation, migration of the cobalt corrosion product may occur, such as metal atoms, organic and inorganic material, on and inside the porous dielectric surface through diffusion, as illustrated in step C of FIG. 1. Previously known dry-wet cycles only enhanced such diffusion and left surface contamination to anchor onto the surface and migrate into the dielectric material. The precipitation of contaminants on the ILD result in leakage or shorts between the conductive features leading to substantial yield loss.

As a result, an enhanced ELD process is disclosed that provides contaminant-free and residue-free dielectric surface after the ELD process. The various embodiments described hereunder provide an effective way of preserving the characteristics of the dielectric material using an integrated wet process. The integrated wet process described herein prevents and reduces such contamination due to precipitation and migration by keeping the surface of the substrate wet and by passivating the cobalt deposition after the ELD capping process. The surface is kept wet by maintaining a thin layer of transfer film on the porous dielectric surface of the substrate. The transfer film is defined in part by the deposition fluid used during the deposition process in the ELD module. For instance, based on the composition of the deposition fluid, the composition and application parameters, such as concentration, flow-rate, etc., of a post-deposition fluid defining a transfer film may be determined so as to effectuate passivation of the cobalt deposition. The thin layer of transfer film on the dielectric material surrounding the conductive features largely prevents contaminants from the capping process, such as metal containing species, organic and inorganic material, from being trapped in the pores of the dielectric material by providing an effective barrier so as to prevent anchoring of the metal containing species on the surface of the substrate. Thus, after the ELD capping process, the surface of the substrate is maintained wet by subjecting the substrate to a rinse cycle using either an inhibitor chemical that defines a transfer film, as illustrated in step D1 of FIG. 1, or an acid and an inhibitor chemical that defines a different type of transfer film, as illustrated in step D2 of FIG. 1. The embodiment using acid to treat the surface of the substrate is exemplary and should not be considered limiting. Chemicals with strong basic or neutral properties can also be used along with an inhibitor to treat the surface of the substrate so long as the functionality of the application is maintained. The integrated wet process described in steps D1 or D2 provides various benefits including, but not limited to, reduced process time resulting in improved throughput, simplified chemical introduction resulting in reduced production cost; improved yield due to prevention of dry-wet cycles that formerly resulted in agglomeration of contaminants on the surface of the substrate; enhanced ELD process by reducing corrosion; and suppression of other chemical reactions and/or transformation of materials commonly caused due to exposure of conductive features to oxygen and ambient air.

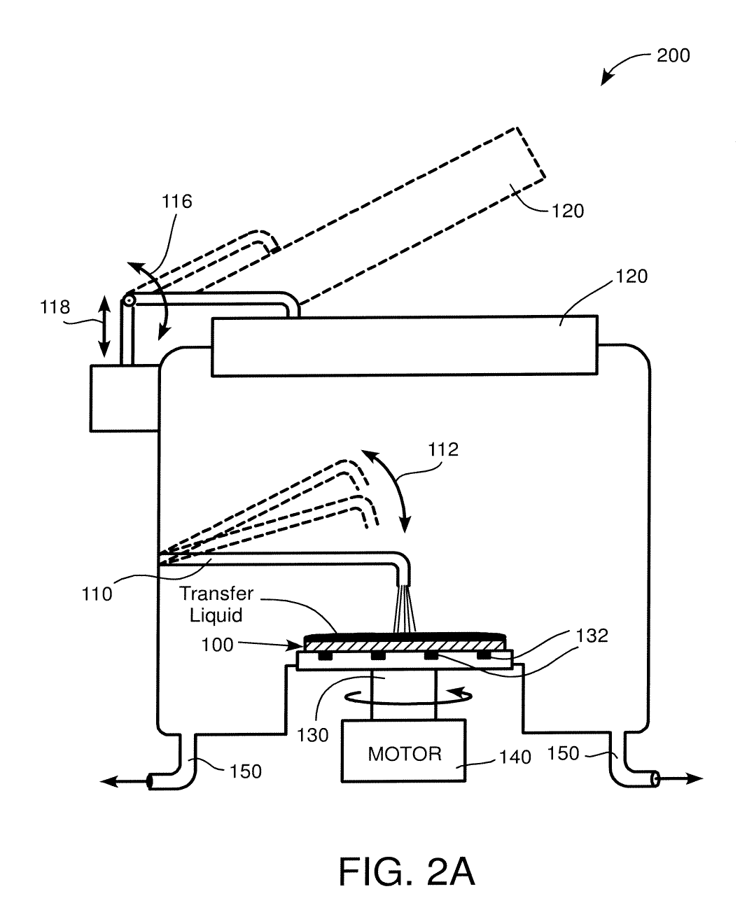

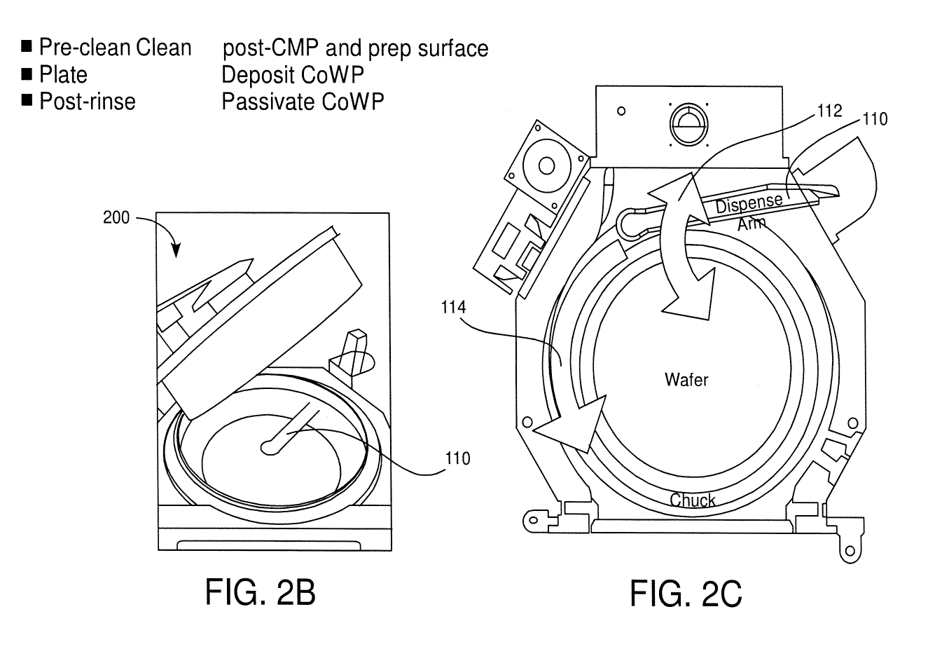

FIGS. 2A, 2B and 2C illustrate an exemplary Electroless Deposition (ELD) module used in handling a substrate through an integrated electroless deposition process, in one embodiment of the invention. The ELD module illustrated in FIGS. 2A, 2B and 2C is similar to the ELD module used in conventional electroless deposition process, such as the one described in U.S. Pat. No. 6,913,651, issued on Jul. 5, 2005 and entitled “APPARATUS AND METHOD FOR ELECTROLESS DEPOSITION OF MATERIALS ON SEMICONDUCTOR SUBSTRATES,” which is incorporated herein by reference. For instance, FIG. 2A illustrates a simplified block representation of an exemplary ELD module, in one embodiment of the invention; FIG. 2B illustrates a schematic top view with a lid partially open; and FIG. 2C illustrates a schematic top view with the lid removed for the purpose of illustration identifying the various components of the ELD module.

The ELD module 200 is used to prepare a top surface of the substrate for deposition and is configured to pre-clean, perform the ELD process to cap the conductive features formed on the surface of the substrate, rinse the surface of the substrate and coat a post-deposition fluid film so as to prevent de-wetting of the surface of the substrate. Towards this end, the ELD module 200 includes a mechanism to receive, hold and spin the substrate along an axis of rotation. The electroless deposition module is configured to isolate the substrate from ambient air and to modulate the oxygen level within to a desired concentration. In one embodiment, the mechanism to receive the substrate is a chuck 130 that is used within the ELD module to receive, hold and spin the substrate along the axis of rotation. The chuck mechanism is described in U.S. Pat. No. 6,935,638, issued on Aug. 30, 2005 and entitled, “UNIVERSAL SUBSTRATE HOLDER FOR TREATING OBJECTS IN FLUIDS,” which is incorporated herein by reference. The embodiments are not restricted to a chuck mechanism for receiving, holding and spinning the substrate but can include other forms of substrate receiving mechanism so long as the mechanism is able to receive, hold and spin the substrate along the axis of rotation within the ELD module. The chuck 130 includes a plurality of chuck pins 132 that extend and retract to receive and release the substrate, respectively. The chuck pins 132 are an exemplary form of receiving, holding and releasing the substrate. The embodiments are not restricted to the chuck pins 132 but can engage other types of mechanism to receive, hold and release the substrate. As illustrated in FIG. 2A, the chuck 130 is powered by a motor mechanism 140 to enable the chuck 130 to spin along an axis of rotation so as to uniformly expose the surface of the substrate to deposition fluid applied to the substrate during the electroless deposition process.

The ELD module includes an arm, such as a first arm 110, to supply a rinsing chemistry to pre-clean the substrate before the deposition process. In one embodiment, the first arm 110 is configured as a moveable arm that moves along a radial path from a periphery to the center of the ELD module, as shown by arrow 112 in FIGS. 2A and 2C, so as to apply the rinsing chemistry to the surface of the substrate when engaged. The substrate is rotated along an axis of rotation, as shown by arrow 114 in FIG. 2C, so as to substantially expose various areas of the surface of the substrate to the rinsing and other chemistries applied through the first arm 110.

The ELD module includes a lid 120 to tightly seal the ELD module during the deposition process, as illustrated in FIGS. 2A and 2B. The lid 120 is configured to swing radially along a hinge provided at the ELD module, as shown by arrow 116 in FIG. 2A, so as to tightly seal the ELD module when the lid is engaged. Alternately, the lid could be configured to move vertically along an axis, as illustrated by arrow 118 in FIG. 2A, instead of radially so that when the lid is moved down, the ELD module is tightly sealed. In another alternate arrangement, the lid 120 may be configured to move both vertically along an axis and in an arc swing-type motion around a hinge so as to seal the ELD module when the lid 120 is engaged and expose the ELD module when the lid 120 is disengaged. Thus, the lid 120 can be configured in different ways to seal the ELD module when engaged.

A second arm (not shown) disposed in the ELD module is used to supply a deposition fluid to the surface of the substrate. In one embodiment, the second arm is disposed on the underside of the lid 120 of the ELD module so that when the lid 120 is engaged, the second arm is configured to supply the deposition fluid to the surface of the substrate in the ELD module and when the lid is disengaged, the supply of the deposition fluid ceases. In one embodiment, the second arm is stationary.

In one embodiment, the deposition fluid is heated outside of the ELD module in a separate microwave/RF unit and discharged into the ELD module at a prescribed temperature. In another embodiment, the ELD module is equipped with a heating element to heat one or more chemistries that is delivered to the ELD module. In this embodiment, a substrate supporting mechanism, such as a chuck, in the ELD module could be equipped with heating elements and thermocouples or other means of heating to heat the deposition fluid and or substrate to a deposition temperature. In this embodiment with heating elements, the heating elements would heat the chuck, which in turn heats the substrate and deposition fluid received thereon. When the heated deposition fluid is at or reaches the deposition temperature, a deposition reaction is triggered causing deposition of a layer of deposition fluid over conductive features on the substrate.

Upon completion of the deposition process the substrate is rinsed by applying a rinsing fluid in the ELD module. The application of the rinsing fluid is controlled to substantially rinse the substrate to remove left-over deposition fluid from the areas of the surface of the substrate that were not intended to receive the deposition fluid, protect metal surface with proper passivation, and, prevent de-wetting of the surface. The rinsing fluid acts as a transfer film over the surface of the substrate keeping the surface of the substrate wet. It should be noted that, the thin layer of the transfer film remains on the surface of the substrate as the substrate is moved out of the electroless deposition. The controlled application of the post-deposition rinsing fluid after the electroless deposition process enables replacing the layer of deposition fluid with the thin layer of post-deposition rinsing fluid on the surface of the substrate. In one embodiment, the first arm may be engaged to apply the post-deposition rinsing fluid so as to define a transfer film coat over the surface of the substrate. The thin layer of the transfer film prevents the surface of the substrate from getting exposed to the ambient air. As mentioned earlier, exposure to the ambient air might cause residues to precipitate on the substrate surface. The transfer film prevents precipitation and agglomeration of the metal alloys on and inside the porous ILD, thereby preserving the insulating properties of the ILD between metal lines and in the layers, resulting in the optimizing of the TDDB. Referring back to FIG. 2A, in addition to the arms and substrate receiving mechanism, the ELD module may include one or more outlet valves 150 to remove any excess rinsing and deposition fluids from the ELD module.

The substrate is removed from the ELD module with the layer of transfer film maintained on the surface of the substrate. The transfer film keeps the substrate surface wet while the substrate is moved to a post-deposition module for further processing. The transportation of the wet substrate to the post-deposition module is performed in the controlled environment of the ELD system.

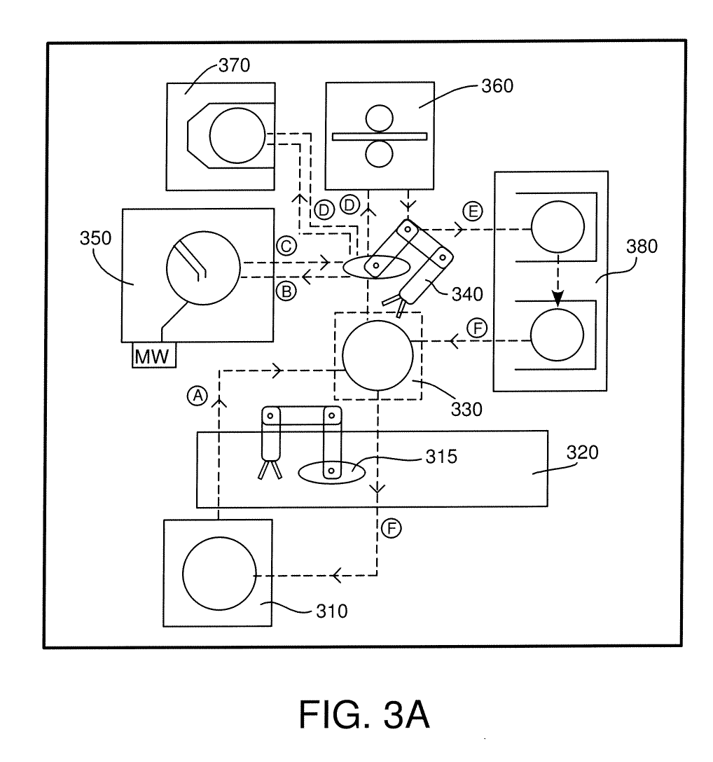

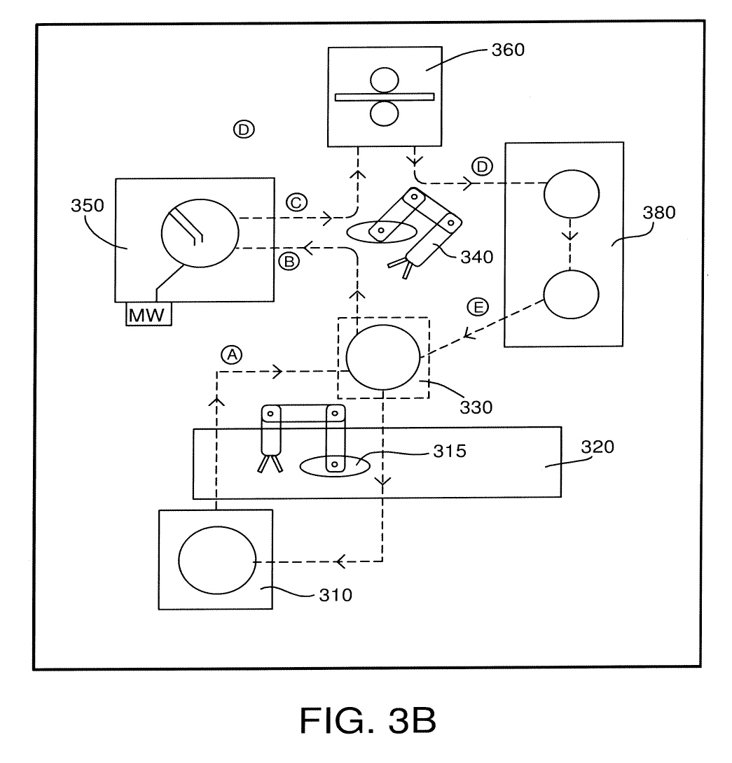

An electroless deposition system will now be described with reference to FIGS. 3A and 3B. FIGS. 3A and 3B illustrate simplified block diagrams of alternate embodiments of an ELD system identifying some of the components.

Referring to FIG. 3A, the ELD system includes a substrate receiving mechanism, a substrate delivery mechanism, and one or more modules to process the surface of the substrate during the ELD process. The substrate is received into the ELD system dry through a loading port. The loading port includes a plurality of substrate receiving units. The substrate receiving units are conventional substrate receiving mechanism, such as a front-opening unified pod (FOUP) 310. The environment within the ELD system is controlled during the deposition process so as to avoid exposing the substrate to additional contaminants/residues that can destroy or damage the features formed on the substrate. The FOUP 310 receives and delivers the substrate to a transfer shelf 330 within the ELD system and the substrate is moved from the transfer shelf 330 to an ELD module within the ELD system. The FOUP 310 is well known in the art for delivering the substrate into a controlled environment and is not discussed extensively here. Additionally, the FOUP 310 is one form of receiving the substrate into the ELD system and other forms or mechanisms can be used in delivering the substrate into the ELD module. The receiving module within the ELD system, such as an Atmospheric Transfer Machine (ATM) module 320, is maintained in a controlled environment within the ELD system. A substrate delivery mechanism, such as a dry robot 315 within the ELD system is engaged for transferring the substrate. The dry robot 315 is provided at the ATM module 320 and is used, in one embodiment, to retrieve the substrate from the FOUP 310 and deposit the substrate on to the transfer shelf 330, as indicated by path “A” in FIG. 3A. The transfer shelf 330 is an optional component within the ELD system for holding the substrate received from the ATM module 320 prior to being delivered to an ELD module within the ELD system. Alternately, the substrate may be retrieved from the ATM module 320 and delivered directly to an ELD module in the ELD system.

The ELD module 350 is used in the deposition process. Aside from the ELD module 350, the ELD system includes a plurality of modules to perform post-deposition process of the substrate. In addition to the dry robot, the ELD system includes a wet robot 340 to transfer the substrate wet from one module to another within the ELD system. To begin with, the wet robot 340 retrieves the substrate from the transfer shelf 330 or directly from the ATM module 320 and transports the substrate to the ELD module 350, as illustrated by path “B” in FIG. 3A. The ELD module 350 is configured to, a) pre-rinse the surface of the substrate after a fabrication operation, such as a planarization operation, to remove residues left behind from the fabrication operation; b) perform a deposition process on the substrate to deposit a layer of capping metal over conductive features on the surface of the substrate; c) rinse the surface of the substrate with a controlled application of a post-deposition rinsing fluid so as to remove residues left behind by the deposition process and to coat the surface of the substrate with a transfer film, based on the composition of the rinsing fluid, to prevent de-wetting; and d) enable removal of the substrate wet with the transfer film from the ELD module 350. The wet robot 340 assists in the transfer of the wetted substrate from the ELD module 350 to a subsequent post-deposition module in the ELD system while maintaining the substrate's top surface wet.

As the substrate is typically received at the ELD module 350 after a chemical-mechanical polishing (CMP) operation, the substrate surface is cleaned to remove any residues from the CMP operation prior to starting the deposition. As a result, a pre-deposition rinsing fluid is provided at the ELD module 350 to clean the substrate. Typical pre-deposition rinsing fluids that are used in the cleaning operation prior to the deposition process have been described in the following co-pending U.S patent applications: U.S. patent application Ser. No. 11/760,722, filed on Jun. 8, 2007, entitled “SEMICONDUCTOR SYSTEM WITH SURFACE MODIFICATION”, U.S. patent application Ser. No. 12/205,894, filed on Sep. 7, 2008, entitled “CLEANING SOLUTION FORMULATIONS FOR SUBSTRATES”, Ser. No. 12/334,462, filed on Dec. 13, 2008, entitled “POST-DEPOSITION CLEANING METHODS AND FORMULATIONS FOR SUBSTRATES WITH CAP LAYERS”, Ser. No. 12/334,460, filed on Dec. 13, 2008, entitled “ACTIVATION SOLUTION FOR ELECTROLESS PLATING ON DIELECTRIC LAYERS,” which are incorporated herein by reference. After cleaning the surface of the substrate to remove the residues from the CMP operation, the pre-deposition rinsing fluid is removed from the ELD module 350 through the outlet valves 150, as illustrated in FIG. 2A.

Following the cleaning operation to remove the residues from the CMP operation, the surface of the substrate is subjected to a deposition process within the ELD module 350. In the deposition process, a layer of deposition fluid is deposited over conductive features formed on the surface of the substrate. The formulation of the deposition fluid is such that it creates a cap over the conductive features during selective deposition and to the extent possible, acts as a barrier preventing copper and other metals that are used in forming the conductive features from migrating to the surrounding dielectric layer. In one embodiment, the deposition fluid is cobalt rich to enable forming a cobalt cap over the conductive features on the surface of the substrate. The deposition fluid is carefully selected so as to inhibit oxidation reactions. Towards this end, the deposition fluid includes an inhibitor and chemistry that includes a rich source of active control cobalt ions. Example deposition fluid and application parameters used are described in U.S. Pat. No. 6,911,067, issued on Jun. 28, 2005, and entitled “Solution composition and method for electroless deposition of coatings free of alkali metals” and U.S. Pat. No. 6,902,605, issued on Jun. 7, 2005, and entitled “Activation-free electroless solution for deposition of cobalt and method for deposition of cobalt capping/passivation layer on copper”, and methods for its use have been discussed in U.S. Pat. No. 6,794,288, issued on Sep. 21, 2004, and entitled “Method for electroless deposition of phosphorus-containing metal films onto copper with palladium-free activation” and in co-pending U.S. patent application Ser. Nos. 11/199,620, filed on Aug. 9, 2005, entitled “Methods for forming a barrier layer with periodic concentrations of elements and structures resulting therefrom” and 11/760,722, filed on Jun. 8, 2007, and entitled “Semiconductor System with Surface Modification,” all of which are herein incorporated by reference in their entirety. As mentioned earlier, the deposition fluid is applied to the surface of the substrate through a second arm that acts as a distribution device, in one embodiment of the invention. As mentioned earlier, the second arm can be a spray, a nozzle or any other suitable mechanism so long as it can apply the deposition fluid in a controlled manner over the conductive features formed on the surface of the substrate. In an alternative embodiment, all fluids could be distributed to the substrate from a single arm or distribution device, so long as the fluid is distributed in a controlled fashion over the surface of the substrate.

In one embodiment, the deposition fluid is heated to a reactive temperature prior to being introduced into the ELD module 350 where the deposition reaction takes place on the substrate. The reactive temperature of the deposition fluid varies based on the type of the deposition fluid and the application conditions used. In one embodiment, the deposition temperature is about 70°C. to about 90° C. or as described in U.S. Pat. No. 6,913,651, typically in the range of about 0% to about 25% below the boiling point of the deposition fluid solution.

In one embodiment, the deposition fluid is supplied to the ELD module at mostly a non-reactive temperature. In the ELD module, the deposition fluid is then heated using a heating element to a reactive temperature. As the deposition fluid heats up and approaches the reactive temperature, the humidity within the ELD module increases. In one embodiment, the humidity within the ELD module reaches to about 80%. In another embodiment, the humidity within the ELD module is at about 95%.

As the temperature within the ELD module reaches reactive temperature or when the deposition fluid is introduced into the ELD module preheated to a reactive temperature, a deposition reaction is triggered. The deposition reaction deposits a layer of deposition fluid on the conductive features on the surface of the substrate. After the deposition process, the surface of the substrate is rinsed using a rinsing fluid, such as a post-deposition rinsing fluid. The post-deposition rinsing fluid is defined from the deposition fluid and is applied in a controlled manner onto the surface of the substrate. The post-deposition rinsing fluid rinses the surface and prevents de-wetting of the surface of the substrate by defining and maintaining a transfer film, on the surface of the substrate. The controlled application of the post-deposition rinsing fluid enables replacing the deposition fluid layer from the surface of the substrate with the transfer film. After the application of the post-deposition rinsing fluid, the substrate is removed from the ELD module 350 by a wet robot 340 while maintaining the transfer film on the surface of the substrate. The wet robot 340 moves the substrate wet with the transfer film to a post-deposition module within the ELD system. Thus, as the substrate is kept constantly wet during the integrated ELD process, any residues present in the ELD module, including a droplet of the deposition fluid or any other chemistry/residue that precipitates on the substrate will not damage the substrate or materials thereon during the integrated deposition process.

To efficiently wet the surface of the substrate and to prevent de-wetting of the surface of the substrate, one or more surfactants may be added to the post-deposition rinsing fluid. The surfactants help in uniformly wetting the surface of the substrate by reducing the surface tension of the rinsing fluid. The concentration of the one or more surfactants that have shown effective result range between about 50 parts/million (ppm) to about 2000 ppm. Some of the surfactants that are used herein are described in U.S. patent application Ser. Nos. 12/334,462 and 12/334,460, which are incorporated herein by reference in its entirety. Some sample surfactants may include Linear AlkylBenzene Sulphonate, TRITON™ QS-44, Perfluoro Anionic and nonionic surfactants like Zonyl™ from DuPont and Masurf™ by Mason. In addition to one or more surfactants, one or more chelating agents may be added to the post-deposition rinsing fluid so as to bond with metal containing residues to form complexes. The chelating agents are chosen such that the complexes formed with the metal containing residues are soluble in an aqueous portion/component of the post-deposition rinsing fluid. Some of the chelating agents include Tetra-Methyl Ammonium Hydroxide (TMAH) or MethylAmine (MA) containing metal-chelating agents such as Hydroxyethyl Ethylenediamine Triacetic Acid (HEDTA) and/or Lactic Acid. In one embodiment, the concentration of the chelating agent(s) within the post-deposition rinsing fluid may range between about 100 ppm to about 5000 ppm.

In order to maximize functionality of the chelating agent(s) and the surfactant(s), a pH value of the post-deposition rinsing fluid may be adjusted. The range of pH value that has shown promising results is between about 2.0 pH (acidic) to about 12 (base). In one embodiment, the pH value of the post-deposition rinsing fluid can be adjusted using a pH adjusting agent. The pH adjusting agent can be any one of the surfactants or chelating agents added to the post-deposition rinsing fluid or could be a distinct pH adjusting agent added to the post-deposition rinsing fluid.

In addition to the surfactants, chelating agents and pH adjusting agents, one or more oxygen consuming/reducing agents can also be added to the post-deposition rinsing fluid to effectuate post-deposition cleaning of the substrate. The oxygen reducing agents directly react with the dissolved oxygen molecules in the transfer film in order to reduce the oxygen concentration contained therein. An exemplary oxygen reducing agent that has shown promising results in reducing oxygen concentration in the transfer film on the substrate is dimethylaminobenzaldehyde (DMAB). In one embodiment, in addition to DMAB, a second or additional oxygen reducing agents may be included in the post-deposition rinsing fluid to help reduce oxygen concentration and to recover the first oxygen reducing agent. An exemplary second reducing agent that has shown promising results in reducing oxygen concentration while helping in the recovery of the first oxygen reducing agent is L-ascorbic acid. The concentration of the oxygen reducing agents that have shown promising results are in the range of about 100 ppm to about 5000 ppm.

In addition to the surfactants, chelating agent, oxygen reducing agent and pH adjusting agents, one or more etching inhibitors may be added to the post-deposition rinsing fluid to preserve the layer deposited over the conductive features on the surface of the substrate. In one embodiment, an exemplary etching inhibitor for CoWP capping is benzotriazol. The concentration of such etching inhibitor that has shown promising results is in the range from about 20 ppm to about 2000 ppm. A thickening agent may also be added to the post-deposition rinsing fluid to add thickness to the post-deposition rinsing fluid so that a film of the post-deposition rinsing fluid applied to the surface of the substrate can be maintained over an extended period of time. The thickening agent is selected such that it does not adversely react or otherwise affect the surface of the substrate when applied and maintained for extended period of time. The thickening agent also reduces evaporation rate of the solvent within the post-deposition rinsing fluid. An exemplary thickening agent that has shown promising results is poly-ethanol. The concentration of the thickening agent that has shown promising results range from about 50 ppm to about 5000 ppm.

In addition to the ELD module 350, the ELD system illustrated in FIG. 3A includes a plurality of post-deposition modules, such as a chemical module 370, a brush scrub module 360 and a clean module 380. The substrate is removed from the ELD module 350 with a layer of transfer film wetting the surface of the substrate and introduced into the chemical module 370, as illustrated by path “C” in FIG. 3A. The substrate is received in the chemical module 370 of the post-deposition modules wet with the transfer film covering the surface and an acid containing fluid is applied over the surface of the substrate. The chemical module 370 is configured to apply an acid containing fluid to remove traces of the deposition fluid and the post-deposition rinsing fluid from areas of the substrate surface which were not intended to receive the deposition fluid and post-deposition fluid. In addition to being configured to apply an acid containing fluid, the chemical module 370 may also be configured to apply a basic fluid or a neutral fluid to the surface of the substrate. The type of fluid (acid, basic, or neutral) may be driven by the type of deposition fluid and post-deposition rinsing fluid that is applied to the surface of the substrate. In the embodiment where an acid containing fluid is used, the applied acid containing fluid is rinsed using a rinsing fluid that is defined from the acid containing fluid. The rinsing fluid applied in the chemical module 370 defines a transfer film so as to prevent de-wetting of the surface of the substrate. In one embodiment, the rinsing fluid chemically treats the surface of the substrate while maintaining a layer of transfer film on the surface of the substrate. The chemical module 370 may perform additional treatment, if necessary, while maintaining a layer of the transfer film on the surface of the substrate in between the treatments. In one embodiment, the acid containing fluid is defined from the deposition and post-deposition rinsing fluids used in the electroless deposition module. In one embodiment, the substrate with the transfer film on the surface of the substrate is moved out of the chemical module 370 into another post-deposition module, such as a brush scrub module 360 for further processing, as indicated by path “D” in FIG. 3A.

In another embodiment, the substrate may be moved from the chemical module wet with rinsing fluid into a second chemical module (chemical rinse module) so as to treat the surface of the substrate with a passivation fluid. The operation of the second chemical module is similar to the operation of the chemical module 370 that applied the acid containing fluid to the surface of the substrate. The passivation fluid is introduced to passivate metal lines and pads formed on the surface of the substrate. The passivation fluid is selected based on the substrate layer and metal pads/lines formed on the surface and is used to minimize metal corrosion. In this embodiment, the substrate is received into the chemical rinse module (a second chemical module) wet with the transfer film from the chemical module and the passivation fluid is applied to the surface of the substrate. The passivation fluid replaces the transfer film and passivates the substrate layer and metal pads. After treating the substrate with the passivation fluid, a transfer film, defined by the passivation fluid, is applied to the substrate to rinse the passivation fluid and to wet the surface of the substrate. The wet substrate is moved out of the chemical rinse module while maintaining the transfer film on the surface of the substrate.

The wet robot 340 helps in transferring the substrate wet with the transfer film to a subsequent post-deposition module within the ELD system, such as a brush scrub module 360 as illustrated by path D of FIG. 3A, where the substrate undergoes mechanical clean using a scrubbing chemical and one or more brush units disposed within the brush scrub module 360. In one embodiment, the brush scrub module 360 is similar in structure to the chemical module 370 except for the presence of one or more brush units in the brush scrub module 360 for mechanically cleaning the substrate. The brush scrub module 360 is configured to supply a scrubbing chemical and to scrub the surface of the substrate using the one or more brush units and the supplied scrubbing chemical. The brush scrub module 360 is further configured to apply a transfer film defined from the scrubbing chemical to the surface of the substrate. The transfer film maintains the surface of the substrate wet while the wet robot 340 removes the substrate from the brush scrub module 360 and inserts the substrate into another post-deposition module, such as a clean module 380, as illustrated by path “E” in FIG. 3A. The clean module 380 is configured to rinse and dry the substrate. In one embodiment, the clean module 380 includes one or more proximity heads that are configured to supply a rinsing fluid, rinse the substrate surface using the rinsing fluid and dry the substrate. In one embodiment, the dry substrate is removed from the clean module 380 and transferred to the optional transfer shelf 330 by the wet robot 340, as illustrated by path “F” in FIG. 3A. The dry substrate is moved out of the ELD system by the dry robot 315 through the ATM module 320 and deposited on the FOUP 310. Alternately, the dry substrate is removed from the clean module 380 and transferred to the ATM module 320 directly and is moved out of the ELD system by the dry robot 315 onto the FOUP 310.

FIG. 3B illustrates an alternate embodiment of the ELD system through which the substrate undergoes an integrated electroless deposition process. In this embodiment, the substrate is moved from a FOUP 310 to an ELD module 350 through an ATM module 320 using a dry robot 315 and through an optional transfer shelf 330 using a wet robot 340. The ELD module 350 is configured to apply a pre-deposition rinsing fluid to clean the residues left behind on the surface of the substrate by a previous fabrication operation, such as a CMP process, apply a layer of deposition fluid over the conductive features of the substrate, apply a post-deposition rinsing fluid to rinse the surface of the substrate to remove residues left behind by the deposition fluid. Upon rinsing the surface of the substrate, the ELD module is configured to apply a post-deposition treating fluid to the surface of the substrate in a controlled fashion. The post-deposition treating fluid defines a transfer film on the surface of the substrate so as to prevent de-wetting of the surface and to chemically treat the surface while the transfer film coating is maintained on the surface of the substrate. In one embodiment, a PICO chemistry is used, which includes a surfactant, an inhibitor and an acidic compound so as to appropriately rinse the surface of the substrate.

The wet robot 340 removes the substrate wet with the transfer film from the ELD module 350 and inserts the substrate into a brush scrub module 360 while continuing to maintain the transfer film on the substrate's surface. The only difference between the embodiments illustrated in FIGS. 3A and 3B is the absence of a distinct chemical module 370. Instead, in the embodiment illustrated in FIG. 3B, the ELD module 350 itself is configured to treat the surface of the substrate with the post-deposition rinsing fluid and the post-deposition treating fluid that chemically treats the surface of the substrate and the substrate is transferred wet with the post deposition treating fluid film from the ELD module 350 to the brush scrub module 360. The remaining modules, components and sequence paths remain the same as the embodiment illustrated in FIG. 3A. In one embodiment, the treating fluid is the same chemical as the acid containing fluid used in the chemical module illustrated in FIG. 3A. In another embodiment, the treating fluid is different from the acid containing fluid used in the chemical module of FIG. 3A.

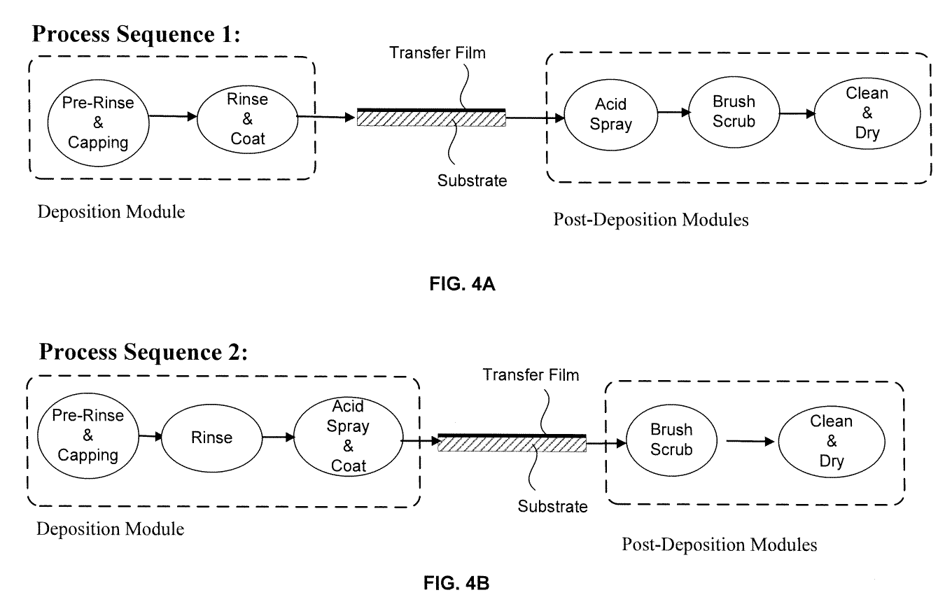

FIGS. 4A and 4B illustrate a brief overview of the process sequence performed in the deposition module and the post-deposition modules defined in the embodiments illustrated in FIGS. 3A and 3B. FIG. 4A briefly lists the sequence of processes performed in each of the modules of the ELD system illustrated in FIG. 3A. Accordingly, an electroless deposition module performs a pre-rinse process to remove the residues left behind by a previous fabrication operation, such as a CMP process, followed by a capping process to cap the conductive features formed on the surface of the substrate. After the capping process, the electroless deposition (ELD) module rinses the substrate using a post-deposition rinsing fluid to remove the residues left behind by the deposition fluid and coats a transfer film defined from the post-deposition rinsing fluid on the surface of the substrate before the substrate is removed wet from the ELD module and inserted into one or more of the post-deposition modules. The post-deposition modules illustrated in FIG. 4A include a chemical module to treat the substrate with an acid containing fluid, a brush scrub module to physically scrub the surface of the substrate using a scrubbing chemical, and clean module to rinse and dry the substrate. The process operations performed in the post-deposition modules are similar to what have been discussed with reference to FIG. 3A.

FIG. 4B briefly lists the sequence of processes performed in each of the modules of the ELD system illustrated in FIG. 3B. Accordingly, the deposition module performs a pre-rinse process to remove the residues left behind by the CMP process, followed by a capping process to cap the conductive features formed on the surface of the substrate. After the capping process, the deposition module rinses the substrate using a post-deposition rinsing chemical to remove the residues left behind by the deposition fluid and applies a treating fluid to define a transfer film coating on the surface of the substrate. The treating fluid prevents undesirable metal surface oxidation and de-wetting while chemically treating the surface of the substrate. After the application of the treating fluid, the substrate is removed from the ELD module while wet with the transfer film and inserted into a post-deposition module. The post-deposition modules illustrated in FIG. 4B include a brush scrub module to physically scrub the surface of the substrate, and a clean module to rinse and dry the substrate.

It should be noted that the above embodiments reflect only two different configurations of the various components and modules of the ELD system. It should be clear to one skilled in the art that there could be variations in the configurations including using more than one ELD module, chemical module, brush scrub module and/or clean module so long as the functionalities of each of the various modules are maintained. Further, there could be variations of the different modules for processing the surface of the substrate within the ELD system. For instance, in an alternate embodiment to the ELD system illustrated in FIGS. 3A and 3B, the ELD system may include an ELD module, a chemical module and a clean module. In yet another embodiment, the ELD system may include an ELD module, a chemical module, a brush scrub module, a second chemical module, and finally a clean module. In still another embodiment, the ELD system may include an ELD module, a brush scrub module, a chemical module, a second brush scrub module and a clean module. As can be envisioned, any number and variation of the modules within the ELD system can be provided for the integrated electroless deposition process and the illustrated embodiments must be considered exemplary and not restrictive by any means.

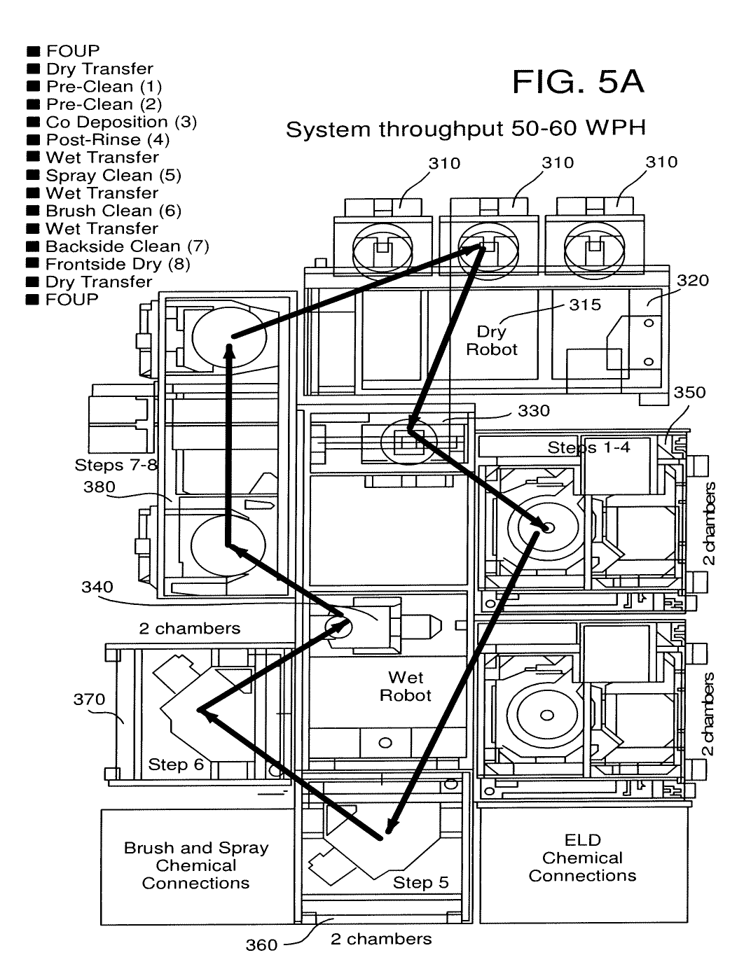

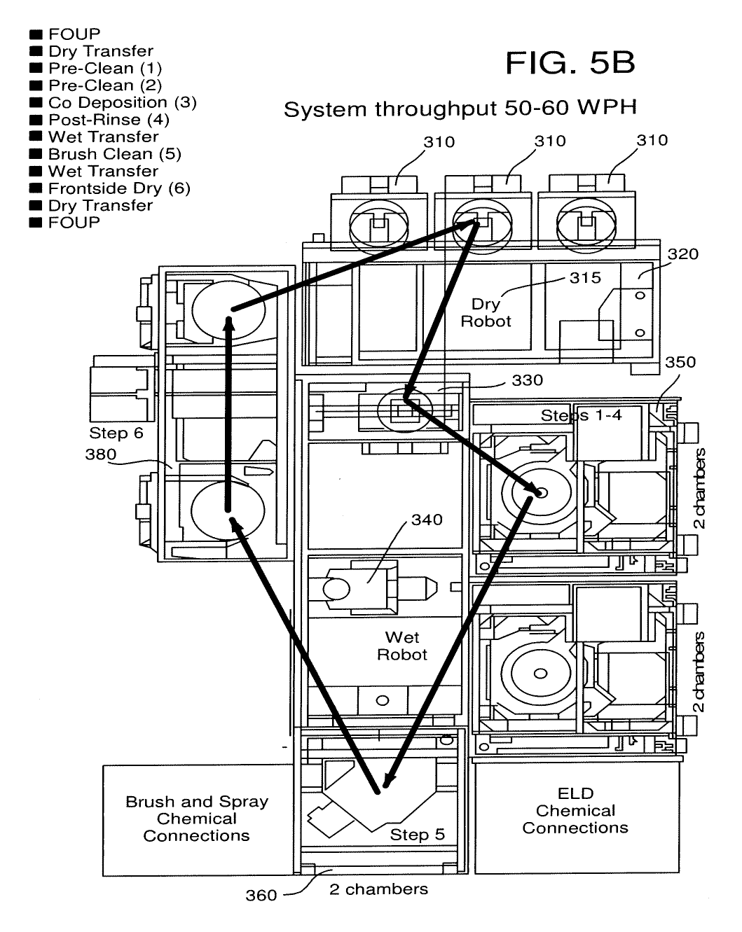

In order to increase the throughput in the ELD system, one or more stacks of modules may be employed. FIGS. 5A and 5B illustrate schematic layouts of ELD systems with integrated stacks of deposition and post-deposition modules for carrying out an integrated electroless deposition process described with reference to FIGS. 3A and 3B, respectively.

Referring now to FIGS. 5A and 5B, the ELD module 350 is an integrated stack of ELD modules 350 arranged vertically and/or horizontally. In one embodiment, the integrated ELD module stack includes two ELD modules 350 stacked one on top of the other so that each module can receive and process a substrate independently. In another embodiment, a plurality of independent ELD module stacks with each ELD module stack having at least two ELD modules stacked one on top of the other, is disposed side-by-side. In the embodiment illustrated in FIGS. 5A and 5B, the system throughput using the integrated ELD module stack is about 50-60 substrates (wafers) per hour (WPH). The components and functionalities of each ELD module 350 are similar to the one described with reference to FIGS. 2A-2C and 3A-3B, respectively.

Continuing to refer to FIGS. 5A and 5B, the embodiments illustrate the various operations that are carried out in the ELD module 350. As shown in FIG. 5A, the substrate received at each of the ELD modules 350 within the ELD module stack undergoes a round of pre-cleaning (step 1) before the deposition process. In an alternate embodiment, the substrate undergoes two rounds of pre-cleaning (steps 1 and 2) before the deposition process to remove the residues and contaminants from earlier fabrication operations, such as copper deposition and CMP processing. In one embodiment, a single post-deposition rinsing fluid is used in the two rounds of cleaning. In another embodiment, each round of cleaning uses different post-deposition rinsing fluids. In one embodiment, the surface of the substrate is treated with deionized water (DIW) after the deposition process and prior to applying a post-deposition rinsing fluid. Although embodiments have been described with reference to performing a single rinse or double rinse within the ELD module, these embodiments should be considered exemplary and should not be considered restrictive. Consequently, multiple rinses (more than two) can be performed in the ELD module prior to applying a transfer film on the surface of the substrate. In one embodiment, the mechanism of the rinse includes transfer of momentum as well as dilution. Since the cobalt ions generally have a negative potential, they dissolve into the aqueous solution of the post-deposition rinsing fluid automatically. Hence, care should be taken in the application and maintenance of the post-deposition rinsing fluid. As a result, the selection and control application of the post-deposition rinsing fluid ensures that there is no adverse effect occurring on the surface of the substrate while maintaining the substrate wet with the transfer film of the rinsing fluid.

Some of the exemplary rinsing fluids that are used during the pre-deposition cleaning of the substrate include citric acid with one or more surfactants, oxalic acid with one or more surfactants, CP-72™, ESC-784™, ESC-90™ from ATMI, etc. The concentration ranges of surfactants are between about 0.1% to about 5% with preferred concentration of about 1%, and a flow rate between about 100 parts per million (ppm) to about 2000 ppm with a preferred flow rate of about 500 ppm. After the pre-deposition clean, the substrate is subjected to a deposition process (step 3) to cap the conductive features formed on the surface of the substrate by applying deposition fluid. During the deposition process, a humid environment is provided within each of the ELD modules by pre-heating and supplying the heated deposition fluid into the ELD modules or heating the deposition fluid within the ELD modules to a deposition temperature and triggering a deposition reaction. After the deposition process, the substrate is rinsed (step 4) in the corresponding ELD modules 350 within the ELD stack wherein the deposition fluid is replaced with a post-deposition rinsing fluid that defines a transfer film on the top surface of the substrate.

Aside from the ELD module stack, the ELD system illustrated in FIGS. 5A and 5B include one or more post-deposition module stacks. Accordingly, in one embodiment illustrated in FIG. 5A, the ELD system includes one or more chemical module stacks, one or more brush scrub module stacks and one or more clean module stacks. Additionally, the post-deposition modules can be integrated. In one embodiment, the chemical module can be integrated with the brush scrub module to provide an integrated chemical cleaning/brush scrub module. In another embodiment, the chemical module is integrated with a clean module so that the substrate can be cleaned with an acid and then rinsed and dried. In yet another embodiment, the brush scrub module is integrated with the clean module. In still another embodiment, the chemical module is integrated with the ELD module so that after the deposition, the substrate can be cleaned with an acid. As can be seen, the various modules can be configured using different configurations to enable the substrate to be substantially processed, cleaned and finally dried after the deposition process.

In the embodiment illustrated in FIG. 5A, following the deposition process in the ELD module stack, the substrate is subjected to a clean using chemical modules 370 (step 5). The functionality provided by the chemical module 370 is similar to that of conventional chemical modules used in the industry and is, therefore, not discussed extensively. As described above, the chemical module 370 could be an integrated chemical module stack with one chemical module stacked on top of the other. The stack is provided to increase the throughput of the substrate in the ELD system. After the acid treatment, the substrate is subjected to a rinse cycle. The rinsing fluid used in the acid treatment defines a transfer film to substantially wet the surface of the substrate. Substantially wet, as used in this application, refers to applying a fluid film (e.g., transfer film) covering the surface of the substrate. Although it is envisioned that the coating be defined on the entire surface of the substrate, complete coating can include situations where portions of the surface of the substrate may not be fully covered. For example, it is possible that non-significant areas may not be covered, such as the edge exclusion, a tiny portion of the substrate surface due to certain feature geometries, a portion covered by an air bubble, etc.

As shown in step 6 of FIG. 5A, the wet substrate is transferred from the chemical module stack to a brush scrub module 360 by the wet robot 340 where the wafer is subjected to mechanical clean using scrubbing chemical and brush units disposed within the brush scrub module 360. In one embodiment, the brush scrub module 360 is similar in structure to the chemical module 370 except for the presence of one or more brush units in the brush scrub module 360 for mechanically cleaning the substrate using a scrubbing chemical. Some of the exemplary scrubbing chemicals that may be used in the brush scrub module include alkaline solutions with Tetra-Methyl Ammonium Hydroxide (TMAH) or MethylAmine (MA) containing metal-chelating agents such as Hydroxyethyl Ethylenediamine Triacetic Acid (HEDTA) and/or Lactic Acid. The concentration for the chelating agent can be between about 0.02 grams/Liter (g/L) and 2 g/L with a preferred concentration of about 0.2 g/L, preferred concentration of TMAH or MA is chosen to obtain pH range of about 10 to about 12.5 with preferred pH range of about 10.7. After the scrubbing process, a transfer film, defined from the scrubbing chemical, is applied to the substrate to prevent de-wetting of the surface of the substrate after the mechanical clean. The transfer film is maintained on the substrate's surface while the substrate is removed from the brush scrub unit to a subsequent module for processing. The brush scrub module illustrated in FIG. 5A can be one or more brush scrub module stacks with each brush scrub module stack having two or more brush scrub modules 360 stacked one on top of the other.

Following the brush clean, the substrate is transported wet to a clean module where the substrate is subjected to a final rinse cycle and dried, as illustrated in steps 7 and 8 of FIG. 5A. In one embodiment, the clean module is a controlled chemical clean (C3) module employing one or more proximity heads. In one embodiment, the C3 module includes a plurality of proximity heads to rinse the front and back of the substrate using a cleaning chemistry (step 7) and to substantially dry the substrate (step 8). The clean module may be a clean module stack with a plurality of proximity heads stacked one on top of the other and/or side-by-side. The dried substrate is transported from the clean module back to the FOUP 310 using the dry robot.

Although the embodiments were discussed with reference to a single wet robot, it should be noted herein that the ELD system could include a plurality of wet robots to transfer the substrate from one module to another. The plurality of wet robots can improve the throughput by simultaneously transferring more than one substrate from one module to another. In one embodiment, the throughput using the ELD system defined with respect to FIG. 5A is about 50-60 substrates (wafers) per hour (WPH).

FIG. 5B illustrates an alternate embodiment of the invention described with respect to FIG. 5A. Similar to the modules in FIG. 5A, the various modules in FIG. 5B could be respective integrated module stacks with each module stack having two or more respective modules stacked one on top of the other and/or side-by-side to increase the throughput. The main difference between the embodiment of FIG. 5B and that of FIG. 5A, is the absence of a distinct chemical module or the chemical module stack. The chemical module may be integrated with the clean module (C3 module) or may be integrated with the brush scrub module or may be integrated with the ELD module. In one embodiment, the chemical module is integrated with the ELD module. As illustrated in FIG. 5B, the substrate undergoes one or more pre-cleans (steps 1 and 2), a deposition process (step 3) and post rinse (step 4) by applying post-deposition rinsing fluid in the ELD module 350 so as to define a transfer film on the surface of the substrate. In one embodiment, the post-deposition rinsing fluid is an acid containing fluid that chemically treats the surface of the substrate when applied to the substrate. The substrate may undergo one more rinsing operation within the ELD module to remove the acid containing fluid and coat the surface of the substrate with a transfer film defined by the post-deposition rinsing fluid used in the rinse operation. The substrate is then transported wet out of the ELD module by a wet robot. In one embodiment, the transfer film on the substrate surface as it comes out of the ELD module prevents de-wetting and chemically treats the surface while maintaining a coating on the surface of the substrate. The substrate with the transfer film is inserted into a brush scrub module 360 (step 5) where the substrate is exposed to mechanical clean. The brush scrub module supplies the scrubbing chemical, performs the scrubbing and applies a transfer film defined from the scrubbing chemical as a coat so as to maintain the substrate surface wet. The wet substrate is transported out of the brush scrub module while continuing to maintain the transfer film on the substrate surface, to a clean module 380 using the wet robot 340 where the substrate is rinsed one last time and dried (step 6). The substantially dry substrate is transported from the clean module 380 back to the FOUP 310 using a dry robot. It should be noted that each of the modules illustrated in FIG. 5B may be a stack of modules to increase the throughput. It should also be noted that the substrate, at this time, coming out of the clean module can be dry on the bottom and dry at the top or wet at the bottom and dry at the top. The resulting substrate is substantially free of corrosions and defects.

Thus, the various embodiments disclose ways to improve the electrical performance of the sub-micron devices formed on the substrate and throughput. The embodiments teach ways to make the substrate substantially defect free and corrosion free by providing a layer of transfer film on the surface of the substrate. The transfer film protects the substrate surface from corrosion by-products, metals and other residues/contaminants by trapping the contaminants and residues that precipitate on the substrate during the deposition/cleaning operations and also ensures that the substrate is not exposed to the ambient air that causes oxidation of the metal implants. Further, the transfer film reduces the wet-dry cycle thereby reducing the moisture breaks which resulted in substantial damage to the substrate due to precipitation of contaminants. The deposition of the cobalt cap on the conductive features and the maintenance of transfer film prevents precipitation and migration of the copper into the surrounding dielectric film layer and the electro-migration of the copper metal alloys thereby preserving the integrated circuit device.

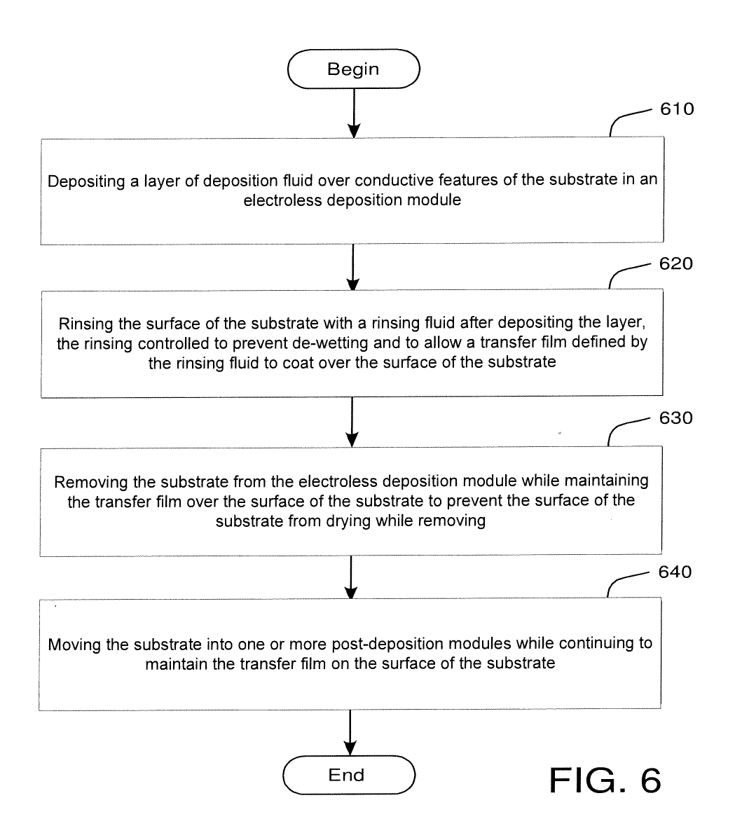

FIG. 6 illustrates a flowchart of process operations for handling a substrate in an integrated deposition process, in one embodiment of the invention. The process begins at operation 610 when a substrate is received through a substrate receiving unit at the loading port and processed by depositing a layer of deposition fluid over conductive features on the surface of the substrate in an ELD module. The substrate may have been subjected to a copper deposition and a CMP process prior to being received for deposition. The substrate can be received through a FOUP into a controlled environment of the ELD system at an Atmospheric Transfer Module (ATM). The substrate at this time is substantially dry. A dry robot available at the ATM retrieves the substrate from the FOUP and deposits it in the ELD module. The structure and function of the ELD module has been described extensively with reference to FIGS. 2A-2C, 3A, and 3B. The substrate is subjected to one or more pre-clean operations in the ELD module. After the pre-clean operation, a deposition operation is performed by supplying deposition fluid to the ELD module and heating the deposition fluid to a deposition temperature so that a deposition reaction occurs. Alternately, the deposition fluid may be pre-heated to a deposition temperature outside the ELD module and introduced into the ELD module for deposition during the deposition process. After deposition, the substrate is rinsed using a post-deposition rinsing fluid within the ELD module, as illustrated in operation 620. The post-deposition rinsing fluid replaces the deposition fluid and defines a transfer film of post-deposition rinsing fluid on the surface of the substrate so as to prevent de-wetting. The post-deposition rinsing fluid may include a surfactant that enables uniform wetting of the substrate surface. The substrate is then removed from the ELD module while continuing to maintain the transfer film over the surface of the substrate, as illustrated in operation 630. The transfer film ensures that the substrate surface is not dry while being transported out of the ELD module. The substrate is moved into a post-deposition module while continuing to maintain the transfer film on the surface of the substrate, as illustrated in operation 640. The process concludes with the substrate getting processed at the various post-deposition modules to get the substrate substantially clean. After obtaining certain level of clean, the substrate is rinsed, dried and delivered through a substrate delivery unit at an unloading port.

The process, thus, defines an efficient way of preventing de-wetting, overcoming problems associated with premature drying and frequent moisture breaks during the integrated electroless deposition process. The resulting substrate is substantially defect-free resulting in substantial electrical yield of the resulting devices.

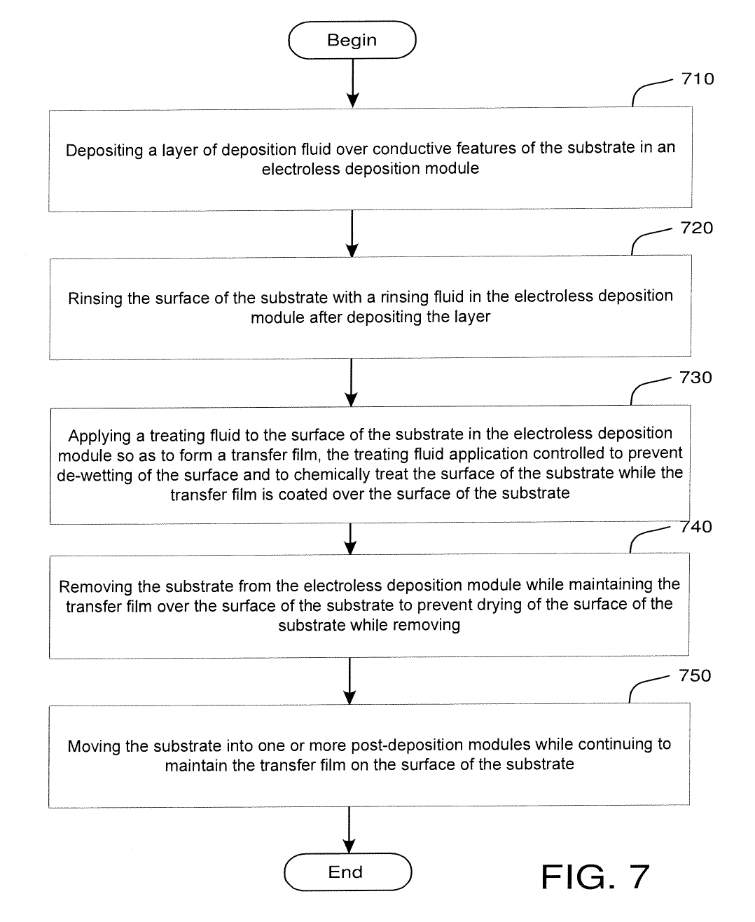

FIG. 7 illustrates a flowchart of process operations for handling a substrate in an integrated deposition process on a surface of a substrate, in an alternate embodiment of the invention. The process begins at operation 710 when a substrate is received into the ELD module through a substrate receiving unit of a loading port and processed by depositing a layer of deposition fluid over conductive features on the surface of the substrate. The substrate is received into an ELD module after a copper deposition process which defines features and a CMP. The structure of the ELD module and process sequence has been described extensively with reference to FIGS. 2A-2C, 3A-3B and 4A-4B. The substrate undergoes one or more pre-clean operations in the ELD module followed by a deposition process. The deposition process is performed by supplying deposition fluid to the ELD module and depositing onto the conductive features on the surface of the substrate. After deposition, the substrate is rinsed using a rinsing fluid in the ELD module, as illustrated in operation 720. After the rinsing operation, a treating fluid is applied to the substrate surface such that a transfer film is defined on the surface of the substrate, as illustrated in operation 730. The treating fluid is applied in a controlled manner so as to prevent de-wetting of the surface and to chemically treat the surface of the substrate while maintaining a coat over the surface of the substrate. In order to prevent de-wetting, the treating fluid defined from the rinsing and deposition fluids includes a surfactant that enables uniform wetting of the surface of the substrate. In order to chemically treat the substrate, the treating fluid may include an inhibitor. The substrate is then removed from the ELD module while maintaining the transfer film of treating fluid over the surface of the substrate, as illustrated in operation 740. The transfer film ensures that the substrate surface is wet while being transported out of the ELD module. The substrate is moved into a post-deposition module while continuing to maintain the transfer film on the surface of the substrate during transfer and before/after processing at each of the modules, as illustrated in operation 750. The process concludes with the substrate getting processed at the various post-deposition modules.

In one embodiment, the treating fluid may include an inhibitor to prevent corrosion of the conductive features and an acid containing fluid that acts as an active agent to enable chemical reaction with the substrate surface. It should be noted that during the integrated ELD process the substrate can be dry on the bottom surface but wet on the top surface or the substrate could be wet on both the bottom and top surfaces. At any rate, it is critical that after each process in the ELD system the substrate is kept sufficiently wet on at least the top surface during transfer of the substrate from one module to another module within the ELD system. After the sequence of processing operations at the different post-deposition modules, the substrate is rinsed and dried. The resulting substrate is substantially clean and defect/corrosion free.

The selection of the various post-deposition rinsing fluids and treating fluid are based on the amount of clean that is required, the nature and type of the pre-deposition fabrication operation, the fabrication chemistries used and the type of substrate. Similarly, the process parameters used to apply the cleaning chemistries varies based on the analysis of the type of fabrication layers that form the features.

For additional information with respect to the proximity head, reference can be made to an exemplary proximity head, as described in the U.S. Pat. No. 6,616,772, issued on Sep. 9, 2003 and entitled “METHODS FOR WAFER PROXIMITY CLEANING AND DRYING.” This U.S. patent, which is assigned to Lam Research Corporation, the assignee of the subject application, is incorporated herein by reference.

For additional information about menisci, reference can be made to U.S. Pat. No. 6,998,327, issued on Jan. 24, 2005 and entitled “METHODS AND SYSTEMS FOR PROCESSING A SUBSTRATE USING A DYNAMIC LIQUID MENISCUS,” and U.S. Pat. No. 6,998,326, issued on Jan. 24, 2005 and entitled “PHOBIC BARRIER MENISCUS SEPARATION AND CONTAINMENT.” These U.S. patents, which are assigned to the assignee of the subject application, are incorporated herein by reference in their entirety for all purposes.

For additional information about top and bottom menisci, reference can be made to the exemplary meniscus, as disclosed in U.S. patent application Ser. No. 10/330,843, filed on Dec. 24, 2002 and entitled “MENISCUS, VACUUM, IPA VAPOR, DRYING MANIFOLD.” This U.S. patent, which is assigned to Lam Research Corporation, the assignee of the subject application, is incorporated herein by reference.

While this invention has been described in terms of several embodiments, it will be appreciated that those skilled in the art upon reading the preceding specifications and studying the drawings will realize various alterations, additions, permutations and equivalents thereof. Therefore, it is intended that the present invention includes all such alterations, additions, permutations, and equivalents as fall within the true spirit and scope of the invention. In the claims, elements and/or steps do not imply any particular order of operation, unless explicitly stated in the claims.

What is claimed is:

1. A method for handling a substrate through processes including an integrated electroless deposition process, comprising:
(a) processing a surface of the substrate in an electroless deposition module to deposit a layer over conductive features of the substrate using a deposition fluid;
(b) rinsing the surface of the substrate in the electroless deposition module with a rinsing fluid, the rinsing being controlled to prevent de-wetting of the surface so that a transfer film defined from the rinsing fluid remains coated over the surface of the substrate;
(c) removing the substrate out of the electroless deposition module while maintaining the transfer film over the surface of the substrate, the transfer film over the surface of the substrate prevents drying of the surface of the substrate so that the removing is wet; and
(d) moving the substrate, once removed from the electroless deposition module, into a post-deposition module, the moving of the substrate being conducted while maintaining the transfer film over the surface of the substrate.

2. The method of claim 1, wherein controlling the rinse further comprising,
including a surfactant in the rinsing fluid, the surfactant enabling wetting the surface of the substrate so as to evenly coat the surface of the substrate with the transfer film from the rinsing fluid.

3. The method of claim 1, further comprising;
receiving the substrate while wet with the transfer film, in a chemical module of the post-deposition module;
applying an acid containing fluid over the surface of the substrate to remove traces of the deposition fluid from areas of the surface of the substrate that was not intended to receive the deposition fluid; and
applying a rinsing fluid to remove the acid containing fluid from the surface of the substrate, the rinsing fluid being controlled to define a transfer film on the surface of the substrate so as to prevent de-wetting.

4. The method of claim 3, further comprising:
moving the substrate out of the chemical module while the surface of the substrate is wet with the transfer film;
inserting the substrate into a brush scrub module of the post-deposition module;
scrubbing the substrate using a scrubbing chemical; and
leaving the substrate wet with a transfer film defined from the scrubbing chemical, the transfer film maintaining the surface of the substrate wet.

5. The method of claim 4, further comprising:
moving the substrate out of the brush scrub module while the surface of the substrate is wet with the transfer film; and
inserting the substrate into a clean module.

6. The method of claim 5, wherein the clean module is a proximity head configured to rinse and dry the substrate.

7. The method of claim 1, wherein the deposition fluid includes cobalt so that the layer over the conductive features of the substrate defines a cobalt capping material.

8. The method of claim 1, wherein the transfer film acts as a barrier to avoid exposure to oxygen so as to prevent oxidation, chemical reactions, or transformations of the deposited layer formed over the conductive features of the substrate.

9. The method of claim 1, further comprising:
before performing (a), conducting a pre-cleaning operation on the surface of the substrate in the electroless deposition module; and
when performing (a), applying the deposition fluid while maintaining temperature and ambient conditions in the electroless deposition module to enable a deposition reaction to occur that deposits the layer over the conductive features of the substrate using the deposition fluid.

10. A method for handling a substrate through processes including an integrated electroless deposition process, comprising:
(a) processing a surface of the substrate in an electroless deposition module to deposit a layer over conductive features of the substrate using a deposition fluid;
(b) rinsing the surface of the substrate in the electroless deposition module with a rinsing fluid;
(c) applying a treating fluid in the electroless deposition module, the treating fluid defining a transfer film, the applying of the treating fluid being controlled to prevent de-wetting of the surface and to chemically treat the surface while the transfer film remains coated over the surface of the substrate;
(d) removing the substrate out of the electroless deposition module while maintaining the transfer film over the surface of the substrate, the transfer film over the surface of the substrate prevents drying of the surface of the substrate so that the substrate is removed wet; and
(e) moving the substrate, once removed from the electroless deposition module, into a post-deposition module, the moving of the substrate being conducted while maintaining the transfer film over the surface of the substrate.

11. The method of claim 10, wherein applying a treating fluid further includes, including a surfactant in the treating fluid, the surfactant enabling wetting of the surface of the substrate so as to evenly coat the surface of the substrate with the transfer film from the treating fluid; and
including an inhibitor in the treating fluid so as to inhibit chemical reaction at the conductive features on the surface of the substrate,
wherein the transfer film acts as a barrier to avoid exposure to oxygen so as to prevent oxidation, other chemical reactions, or transformation of the deposited metal cap layer over the conductive features of the substrate.

12. The method of claim 10, wherein the treating fluid is an acid containing fluid applied over the surface of the substrate to remove traces of the deposition fluid from areas of the surface of the substrate that was not intended to receive the deposition fluid.

13. The method of claim 12, further comprising:
receiving the substrate while wet with the transfer film, into a brush scrub module of the post-deposition module;
scrubbing the substrate using a scrubbing chemical to remove contaminants and traces of the acid containing fluid from the surface of the substrate; and
leaving the substrate wet with a transfer film defined from the scrubbing chemical, the transfer film maintaining the surface of the substrate wet.

14. The method of claim 13, further comprising:
moving the substrate out of the brush scrub module while the surface of the substrate is wet with the transfer film; and
inserting the substrate into a clean module.

15. The method of claim 14, wherein the clean module is a proximity head configured to rinse and dry the substrate.

16. The method of claim 10, wherein the deposition fluid includes cobalt so that the layer over the conductive features of the substrate defines a cobalt capping material.

17. The method of claim 10, further comprising:
conducting a pre-cleaning operation on the surface of the substrate in the electroless deposition module prior to performing an electroless deposition to deposit the layer over conductive features of the substrate; and
during depositing of the layer, applying the deposition fluid while maintaining temperature and ambient conditions in the electroless deposition module to enable a deposition reaction to occur that selectively deposits the layer over the conductive features of the substrate using the deposition fluid.

18. A system for handling a substrate through processes including an integrated electroless deposition process, comprising:
(a) an electroless deposition module configured to, (a1) process a surface of a substrate by depositing a layer of deposition fluid on conductive features formed on the substrate; and (a2) control the application of a fluid that prevents de-wetting and applies a coating of the fluid over the surface of the substrate; and
(b) a wet robot configured to, (b1) remove the substrate out of the electroless deposition module while maintaining the coating of the fluid over the surface of the substrate; and (b2) move the substrate into a post-deposition module while maintaining the coating of the fluid over the surface of the substrate.

19. The system of claim 18, wherein the electroless deposition module is further configured to apply a pre-deposition rinsing fluid to pre-clean the substrate received therein prior to depositing the layer, the application of the pre-deposition rinsing fluid controlled to remove residues on the surface of the substrate left behind from a previous fabrication operation.

20. The system of claim 18, further includes,
a loading port with a plurality of substrate receiving units to receive the substrate for processing; and
an unloading port with a plurality of substrate delivery units to deliver the substrate after processing.

21. The system of claim 20, further includes,
a dry robot configured to,
(i) move the substrate from the loading port into the electroless deposition module for processing; and
(ii) move the substrate from a post-deposition module to the unloading port after processing,
wherein the substrate is handled dry.

22. The system of claim 18, wherein the post-deposition module includes a chemical module, the chemical module configured to,
receive the substrate with the fluid coated over the surface of the substrate through the wet robot;
apply an acid containing fluid over the surface of the substrate to remove traces of the deposition fluid from areas of the surface of the substrate that was not intended to receive the deposition fluid; and
apply a rinsing fluid to remove the acid containing fluid from the surface of the substrate, the rinsing fluid being controlled to define a transfer film on the substrate so as to prevent de-wetting.

23. The system of claim 22, wherein the post-deposition module includes a brush scrub module, the brush scrub module configured to,
receive the substrate with the transfer film coated over the substrate through the wet robot;
apply a scrubbing chemical to the surface of the substrate;
scrub the substrate using the scrubbing chemical; and
apply a transfer film defined from the scrubbing chemical or other fluid to the surface of the substrate so as to maintain the surface of the substrate wet.

24. The system of claim 23, wherein the post-deposition module includes a clean module, wherein the clean module is configured to,
receive the substrate with the transfer film coated over the substrate through the wet robot; and
rinse and dry the substrate.

25. The system of claim 24, wherein the clean module is a proximity head.

26. A system for handling a substrate through processes including an integrated electroless deposition process, comprising:
(a) an electroless deposition module configured to, (a1) supply a deposition fluid, the deposition fluid used to deposit a layer over conductive features formed on a surface of the substrate; (a2) apply a rinsing fluid to rinse the surface of the substrate, after depositing the layer; (a3) apply a treating fluid to the surface of the substrate, the treating fluid defining a transfer film, wherein the electroless deposition module includes controls to control the application of the treating fluid to prevent de-wetting of the surface and to chemically treat the surface while the transfer film is maintained over the surface of the substrate; and
(b) a wet robot configured to, (b1) remove the substrate out of the electroless deposition module while maintaining the transfer film over the substrate, the transfer film preventing drying of the substrate so that the substrate is removed wet from the electroless deposition module; and
(b2) move the substrate into a post-deposition module while maintaining the transfer film over the substrate.

27. The system of claim 26, wherein the electroless deposition module is further configured to apply a pre-deposition rinsing fluid to pre-clean the substrate received therein prior to depositing the layer, the application of the pre-deposition rinsing fluid is controlled to substantially remove residues on the substrate left behind from a previous fabrication operation.

28. The system of claim 26, further includes,
a loading port with a plurality of substrate receiving units to receive the substrate for processing;
an unloading port with a plurality of substrate delivery units to deliver the substrate after processing; and
a dry robot configured to,
(i) move the substrate from the loading port into the electroless deposition module for processing; and
(ii) move the processed substrate from a post-deposition module to the unloading port after processing,
wherein the substrate is handled dry.

29. The system of claim 26, wherein the post-deposition module includes one of a brush scrub module or a clean module.

30. The system of claim 29, wherein the clean module is a proximity head.
